(19) United States
(12) Patent Application Publication
(10) Pub. No.: US 2013/0308260 A1
(43) Pub. Date: Nov. 21, 2013

(54) SMOKE-FREE VIEWING APPARATUS

(71) Applicant: James P. STEVENSON, Montgomery Village, MD (US)

(72) Inventor: James P. STEVENSON, Montgomery Village, MD (US)

(73) Assignees: Kareem Abdus-Salaam, Bowie, MD (US); James P. Stevenson, Montgomery Village, MD (US)

(21) Appl. No.: 13/473,948

(22) Filed: May 17, 2012

(51) Int. Cl. H05K 7/00; G06F 1/16

(52) U.S. Cl. 361/679.3; 361/679.01; 361/679.56

(57) ABSTRACT

A smoke-free viewing apparatus that comprises an expandable enclosure that is expandable between a collapsed position and an expanded position. The expandable enclosure defines a smoke-free interior area when in the expanded position. The expandable enclosure has at least one transparent section that allows viewing in the smoke-free interior area. An electronic device is disposed in the smoke-free interior area of the expandable enclosure. The electronic device has a display, wherein the display of the electronic device is viewable through the at least one transparent section from outside of the expandable enclosure.

### FIELD OF THE INVENTION

The present invention relates to a smoke-free viewing apparatus that provides clear viewing during a smoke-event. More specifically, the present invention relates to a smoke-free viewing apparatus that incorporates one or more electronic devices therein that can be viewed and manipulated during a smoke-event.

### BACKGROUND OF THE INVENTION

Smoke is sometimes created from numerous accidental sources, such as electrical fires and incendiary cargo as well as intentional sources, such as bombs or surface-to-air missiles, during flight causing smoke to enter the cockpit. During serious emergencies, when dense vision-impairing smoke fills the cockpit, flight crews are often unable to see instruments or through the windshield and outside the aircraft. That may result in complete loss of internal and external visibility for the flight crew. Examples of conventional airplane smoke emergency vision devices are disclosed in U.S. Pat. Nos. 4,832,287, 5,202,796, 5,318,250, 5,947,415, and 6,082,673, the subject matter of each of which is herein incorporated by reference. Such conventional devices, however, are often ineffective during total electrical failure.

Therefore, a need exists for a smoke-free viewing apparatus that provides critical viewing to the flight crew and allows the flight crew to navigate even during a total electrical failure.

### SUMMARY OF THE INVENTION

Accordingly, the present invention relates to a smoke-free viewing apparatus that comprises an expandable enclosure that is expandable between a collapsed position and an expanded position. The expandable enclosure defines a smoke-free interior area when in the expanded position. The expandable enclosure has at least one transparent section that allows viewing in the smoke-free interior area. An electronic device is disposed in the smoke-free interior area of the expandable enclosure. The electronic device has a display, wherein the display of the electronic device is viewable through the at least one transparent section from outside of the expandable enclosure.

The present invention also relates to a smoke-free viewing apparatus for an airplane cockpit that comprises an expandable enclosure that is expandable between a collapsed position and an expanded position. The expandable enclosure is configured to fit in the airplane cockpit when the expandable enclosure is in the expanded position. The expandable enclosure defines a smoke-free interior area when in the expanded position. The expandable enclosure has at least one transparent section that allows viewing both in the smoke-free interior area and through the expandable enclosure. An electronic device is disposed in the smoke-free interior area of the expandable enclosure. The electronic device has a display, wherein the display of the electronic device is viewable through the at least one transparent section from outside of the expandable enclosure.

The present invention also relates to a smoke-free viewing apparatus for an airplane cockpit that comprises an expandable enclosure that is expandable between a collapsed position and an expanded position. The expandable enclosure is configured to fit in the airplane cockpit when the expandable enclosure is in the expanded position. The expandable enclosure defines a smoke-free interior area when in the expanded position. The expandable enclosure is substantially transparent, thereby allowing viewing both in the smoke-free interior area and through the expandable enclosure from outside of the expandable enclosure. At least one pocket is disposed on the expanding enclosure. The at least one pocket is extendable into the smoke-free interior area. A tablet computer is disposed in the smoke-free interior area of the expandable enclosure, wherein the tablet computer is viewable in the smoke-free interior area from outside of the expandable enclosure and the at least one pocket is reachable to the tablet computer allowing manipulation thereof.

The present invention may also provide a method for deploying a smoke-free viewing apparatus for an airplane cockpit that comprises the steps of providing an expandable enclosure expandable between a collapsed position and an expanded position, the expandable enclosure being configured to fit in the airplane cockpit when the expandable enclosure is in the expanded position, the expandable enclosure defining a smoke-free interior area when in the expanded position, and the expandable enclosure being substantially transparent; manually expanding the expandable enclosure to the expanded position; inserting a tablet computer into the smoke-free interior area expandable enclosure; and viewing the tablet computer in the smoke-free interior area from outside of the expandable enclosure.

Other objects, advantages and salient features of the invention will become apparent from the following detailed description, which, taken in conjunction with the annexed drawings, discloses a preferred embodiment of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a side perspective view of a smoke-free viewing apparatus in accordance with a first exemplary embodiment in of the present invention, showing the smoke-free viewing apparatus in an expanded position in an airplane cockpit;

FIG. 2 is a front view of the smoke-free viewing apparatus illustrated in FIG. 1;

FIG. 3 is an exploded perspective view of the smoke-free viewing apparatus in accordance with an exemplary embodiment, showing a case for holding the smoke-free viewing apparatus;

FIG. 4 is a perspective view of the smoke-free viewing apparatus illustrated in FIG. 3 rolled in a compact orientation for storage in the case;

FIG. 5 is a front perspective view of a smoke-free viewing apparatus in accordance with a second exemplary embodiment of the present invention, showing the smoke-free viewing apparatus in an expanded position;

FIG. 6 is a front perspective view of the smoke-free viewing apparatus illustrated in FIG. 5, showing the smoke-free apparatus in a collapsed position; and

FIG. 7 is a front perspective view of a smoke-free viewing apparatus in accordance with a third exemplary embodiment of the present invention, showing the smoke-free viewing apparatus in an expanded position.

### DETAILED DESCRIPTION OF THE EXEMPLARY EMBODIMENTS

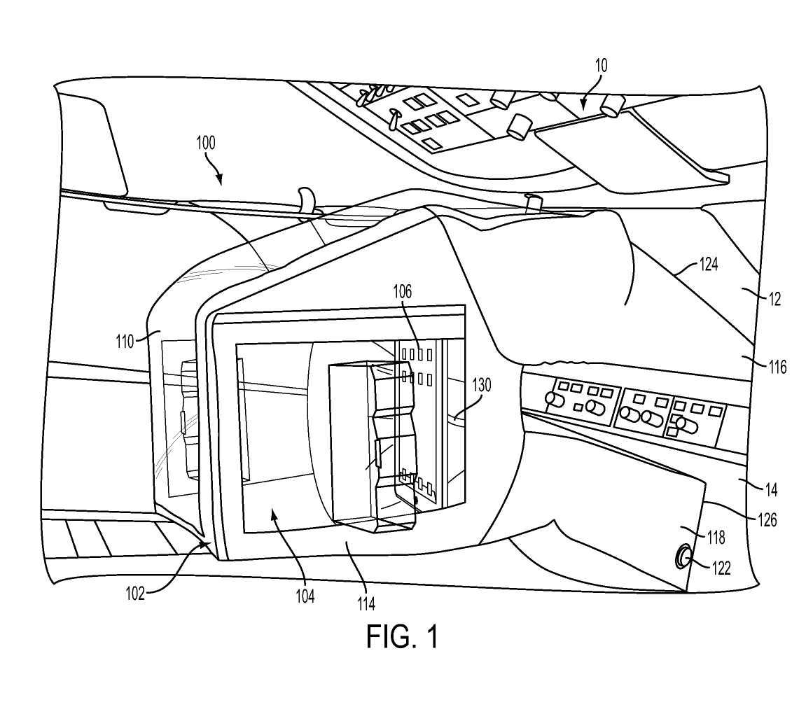

Referring to FIGS. 1-7, the present invention provides a smoke-free viewing apparatus that allows clear viewing during a smoke event. For example, in the event of an electrical fire in an airplane cockpit, the smoke-free viewing apparatus allows clear viewing of electronic devices, instruments, and windshields of the cockpit. In a preferred embodiment, the smoke-free apparatus incorporates a tablet computer therein that has navigational software, which can be viewed and manipulated using the smoke-free viewing apparatus, thereby allowing airplane navigation even in total electrical failure during a smoke event. Although a tablet computer is preferably used with the smoke-free viewing apparatus of the present invention, any electronic device with a display that may be viewed in the apparatus, can be used with the apparatus.

In general, the smoke-free viewing apparatus 100 of the present invention includes an expandable enclosure 102. The expandable enclosure 102 is formed of a material that allows the enclosure to expand from a collapsed position (FIG. 4) to an expanded position (FIG. 1). For example, the enclosure 102 may be formed of any thin plastic material. In its expanded position, the enclosure 102 defines a smoke-free interior area 104, as seen in FIG. 1. When expanded, the viewing apparatus 100 is sized to fit in an airplane cockpit 10 generally between the pilot and the front windshield 12 of the airplane. In a preferred embodiment, a tablet computer 106 is positioned inside of the smoke-free interior area 104.

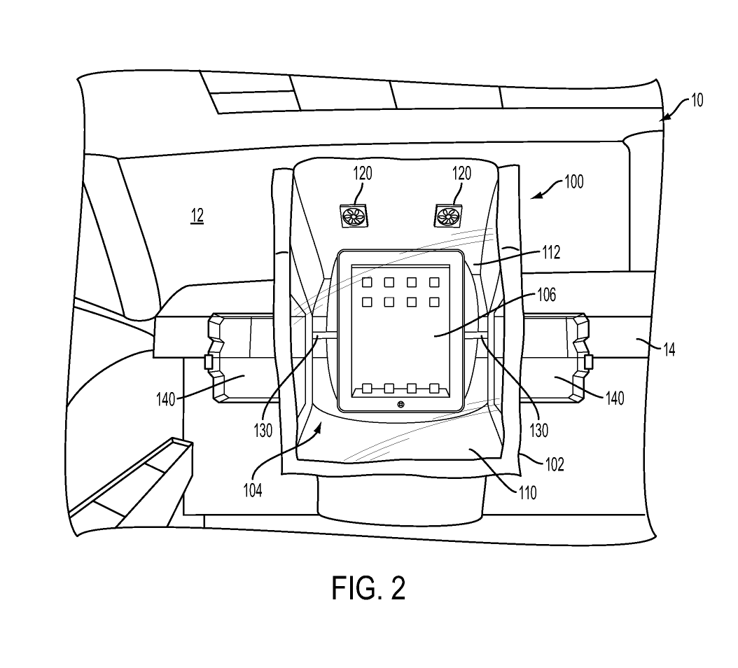

The expandable enclosure 102 is preferably substantially transparent, thereby allowing the pilot to see both inside of the smoke-free interior area 104 and through the interior area 104 to the front windshield 12 for viewing outside of the airplane. In particular, the expandable enclosure 102 includes a primary transparent wall 110 that may be positioned directly in front of the pilot allowing the pilot to at least view the display of the tablet computer 106 in the interior area 104. The enclosure 102 may include another transparent wall 112 (FIG. 2) that is opposite the primary wall 110 that allows view through the enclosure 102, such as to the front windshield 12 or instrument panel 14 of the airplane cockpit. The tablet computer 106 is preferably located between the transparent walls 110 and 112. Side walls 114 of the enclosure 102 may also be transparent. In the embodiment shown in FIG. 1, the expandable enclosure 102 may include a first channel 116 that incorporates the transparent wall 112 and extends to the front windshield 14, thereby allowing the pilot to view outside of the front windshield 12. The end 124 of the channel 116 preferably seals to the windshield 12 such that no smoke is allowed between the channel 116 and the front windshield 12. The enclosure 102 may also include a second channel 118 that extends to the instrument panel 14 and has a transparent wall at the end 126 thereof that allows viewing of the instrument panel 14. As such, the pilot looking through the primary transparent wall 110 of the enclosure 102 can see several things, including in the smoke-free interior area 104 and the tablet computer 106, through the smoke-free interior area 104 to the front windshield 12 via first channel 116, and through the smoke-free interior area 104 to the instrument panel 14 via the second channel 118.

The interior area 104 of the enclosure 102 remains smoke-free by one or more filter members 120. The filter members 120 are preferably fans with a filter attached thereto that is embedded in the walls of the enclosure 102, as seen in FIG. 2. The filter members 120 may be provided in any wall of the enclosure 102 and are preferably flat to facilitate collapse and storage of the enclosure 102. Batteries may be attached to the enclosure 102 to provide power to the filter members 120. A relief valve 122 may also be provided in the enclosure 102 to maintain proper air pressure within the enclosure 102, particularly as the airplane looses and/or gains altitude.

The tablet computer 106 preferably includes navigation software that would allow a pilot to navigate and control the plane even in the event of total electrical failure in the cockpit. For example, the tablet computer 106 may provide a synthetic view of the outside of the cockpit and display critical measurements, thereby allowing the pilot to navigate the airplane. The tablet computer 106 is supported upright in the interior area 104 of the enclosure 102 by one or more support members 130. The support members 130 may be, for example, two or more straps extending between the sidewalls 114 behind the tablet computer 106, thereby allowing the tablet computer 106 to lean or rest on the straps. The tablet computer 106 may be further secured by attaching the tablet computer 106 to the straps 130 in any known manner, such as adhesive or hook and loop.

In order to manipulate the tablet computer 106 in the interior area 104 of the enclosure 102, one or more pockets 140 may be provided on the enclosure 102. The pockets 140 are design to invaginate with respect to the enclosure 102, thereby allowing the pilot to insert his or her hands in the pockets 140 and manipulate the tablet computer 106. The pockets 140 are preferably clear plastic sleeves that are located on the sidewalls 114 of the enclosure, as seen in FIGS. 1 and 2.

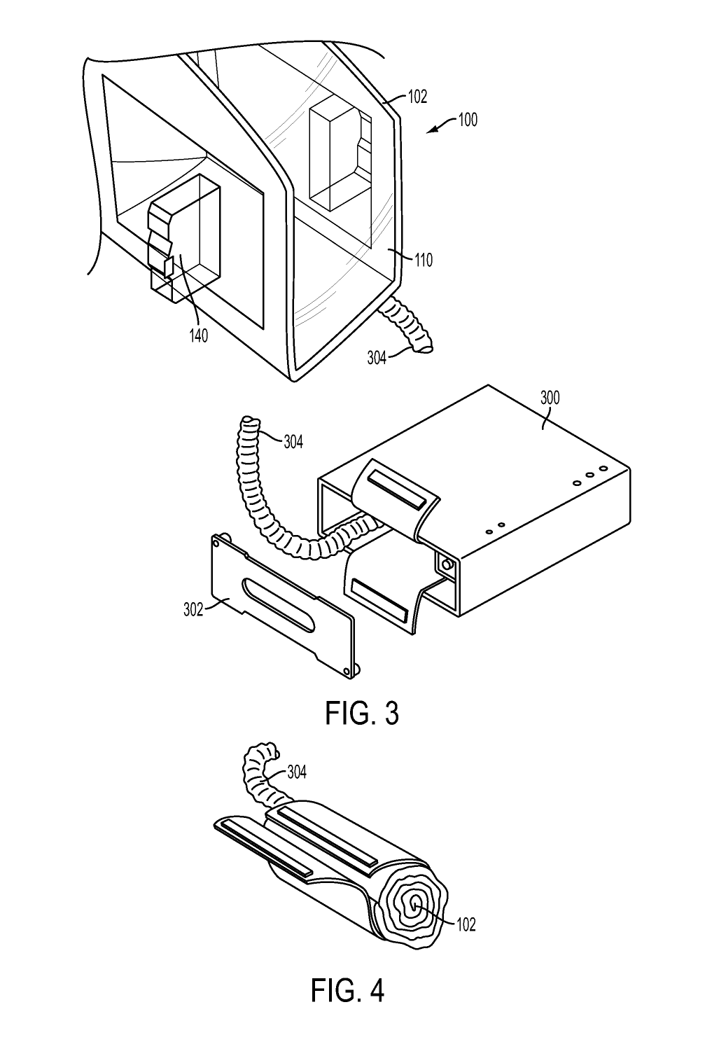

As seen in FIGS. 3 and 4, the smoke-free viewing apparatus 100 may be contained in a case 300 for compact storage in the airplane cockpit. The expandable enclosure 102 is preferably rolled up for storage, as seen in FIG. 4. The case 300 has a removable cover 302 that allows access to the smoke-free viewing apparatus 100 stowed therein. A power source and blower (not shown) are provided in the case 300 that is connected to the expandable enclosure 102 by tubing 304.

In operation, during a smoke event, the pilot puts on goggles and a mask and removes the smoke-free viewing apparatus 100 from its case 300 via removable cover 302. As soon as the apparatus 100 is removed from the case, the blower begins to inflate the expandable enclosure 102. The pilot can then turn on the fans of the filter members 120 ensuring no smoke enters the interior area 104 of the enclosure. Next, the pilot can insert the tablet computer 106 through a self closing slot in the enclosure 102. Any smoke that my leak in will be cleared by the filter members 120. Once fully inflated and the enclosure 102 is in its expanded position, the apparatus 100 can be position in front of the pilot such that the first channel 116 seals against the front windshield 12 and the second channel 118 meets the instrument panel 14. The pilot can then look through the enclosure 102 to see outside of the front windshield 12, the instrument panel 14, and/or the display of the tablet computer 106.

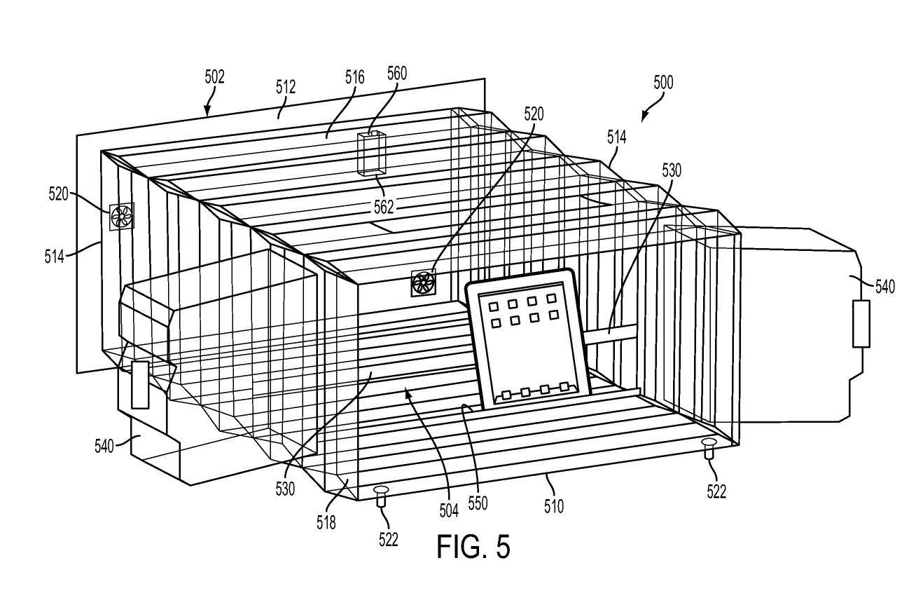

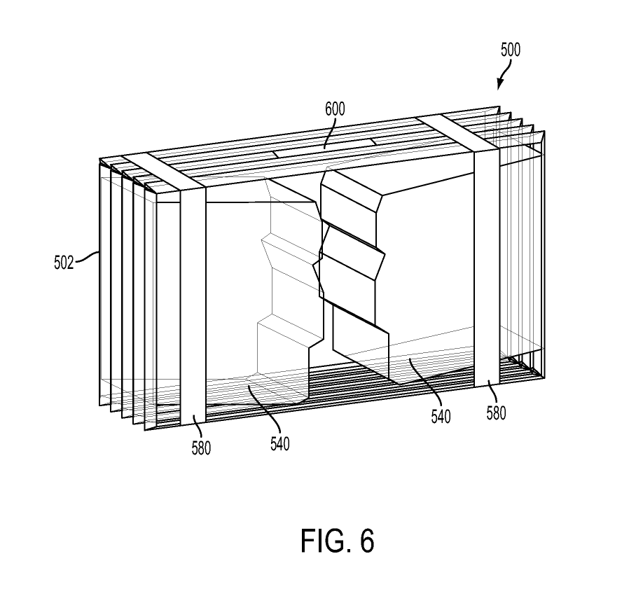

FIGS. 5 and 6 illustrate a second exemplary embodiment of the present invention. The smoke-free viewing apparatus 500 of the second embodiment is similar to the smoke-free viewing apparatus 100 in that it includes an expandable enclosure 502 with a smoke-free interior area 504 that supports an electronic device, such as a tablet computer 106. The expandable enclosure 502 is preferably substantially transparent to allow the pilot to see both inside of the smoke-free interior area 504 and through the interior area 504. The expandable enclosure 502 includes opposite first and second transparent walls 510 and 512 with sidewalls 514 extending therebetween. Additionally, walls 516 and 518 extend between the first and second walls 510 and 512 and the sidewalls 514. Although the enclosure 502 preferably has a generally rectangular or square shape in cross-section, as seen in FIG. 5, the enclosure 502 may have any shape in cross-section, such as triangular, circular, trapezoidal, and the like.

One or more filter members 520 similar to the filter members 120 of the first embodiment may be provided in any of the walls of the enclosure 502. Preferably, the filter members 520 are provided in second wall 512, to facilitate collapse of the enclosure 502, as seen in FIG. 6. One or more relief valves 522 may also be provided in any of the walls of the enclosure 502, such as wall 518.

The tablet computer 106 is preferably located generally in the middle of the interior area 504 with one or more support members 530 holding the tablet computer 106. Like in the first embodiment, the support members 530 may be straps extending from the sidewalls 514. To provide further secure the table computer 106, a groove 550 may be provided in one of the walls of the enclosure 502, such as wall 518, that receives an end of the tablet computer 106. A secondary electronic device 560, such as a cellular phone, may also be provided in the interior area 504. For example, the cellular phone 560 may be disposed in a holder 562 on one of the walls of the enclosure 502, such as second wall 512.

The expandable enclosure 502 may also include one or more pockets 540 similar to the pockets 140 of the first embodiment. The pockets 540 may be located on the sidewalls 514 and extend into the interior area 504 and reach the tablet computer 106 and/or the cellular phone 560 for manipulation of the same.

A pilot using the smoke-free viewing apparatus 500 would position the enclosure 504 such that the pilot can look through the first wall 510 and view the smoke-free interior area 504 and the tablet computer 106. The pilot may also look through the interior area 504 and through the second wall 512. The second wall 512 may include an embedded wire frame 570 that allows the second wall 512 to closely conform to the shape of the windshield 12 of the cockpit such that the pilot can see outside of the windshield 12.

As seen in FIG. 6, the enclosure 502 can be collapsed accordion style with the pockets 540 extending into the interior area 504. One or more straps 580 may be provided that wrap around the collapsed enclosure 502 for compact storage of the same.

In operation, the pilot would release the straps 580 and manually expand the enclosure 502 similar to an accordion by separating the first and second walls 510 and 512. The enclosure 502 may include a wire spring member to facilitate expansion of the enclosure 502. Alternatively, the enclosure 502 may be inflated to its expanded position in a manner similar to the enclosure 102 of the first embodiment. The pilot would then insert the tablet computer 106 through a self closing slot 600 (FIG. 6) located in the enclosure 502 and secure the same using straps 530. Next the pilot would turn on the filter members 520 to ensure the interior area 504 of the enclosure 502 is smoke free. With goggles on his or her face, the pilot can then look through the first wall 510 to see the tablet computer 106 and can also insert his or her hands in the pockets 540 to manipulate the tablet computer 106. The second transparent wall 512 will also allow the pilot to see through the interior area 504 to the windshield of the cockpit.

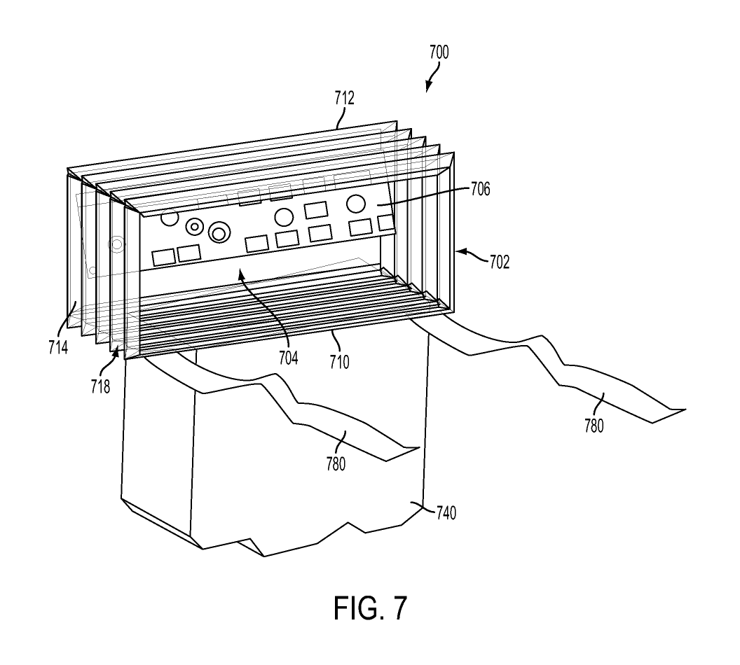

Referring to FIG. 7, a smoke-free viewing apparatus 700 in accordance with a third embodiment of the present invention, is substantially similar to the smoke-free viewing apparatus 500, except that it is smaller and can be pressed against or hold an electronic device. The smoke-free viewing apparatus 700 includes an expandable enclosure 702 that may be expanded and collapsed in the same manner as the enclosure 502 of the second embodiment. The apparatus 700 can be pressed against an electronic device, like an airplane radio 706 that is part of the cockpit instrument panel. An attachment 714, such as adhesive or hook and loop, may be applied to the end 712 of the enclosure 702 that is against the radio 706 to facilitate holding the enclosure 702 against the radio 706. At least one pocket 740 may be provided in a bottom wall 718 of the enclosure 702 for manipulating the radio 706. The opposite end walls 710 and 712 of the enclosure 702 are preferably transparent to provide clear viewing into the interior area 704 of the enclosure 702 and through to the enclosure 702. Alternatively, the electronic device may be inserted into the enclosure 702 in a manner similar to the embodiments above. Like the other embodiments, the enclosure 702 preferably includes filter members to ensure that the interior area 704 remains smoke-free.

Operation of the smoke-free viewing apparatus 700 is similar to that of the smoke-free viewing apparatus 500 of the second embodiment in that the pilot removes the straps 780 and manually expands (or inflates) the enclosure 702. The pilot can then press the end wall 712 against the radio 706 of the instrument panel and manipulate the knobs of the radio through the pocket 740. The pilot will be able to see the radio 706 through the end walls 710 and 712. Alternatively, because the smoke-free viewing apparatus 700 is smaller and thus more manageable, the apparatus 700 can be placed anywhere, including on the pilot's knee. The electronic device can be inserted into the enclosure 702 and the pilot can turn on the filter members to clear the interior area 704. The pilot can then look through the transparent wall 710 and view the display of the electronic device and manipulate the same using the pocket 740.

While particular embodiments have been chosen to illustrate the invention, it will be understood by those skilled in the art that various changes and modifications can be made therein without departing from the scope of the invention as defined in the appended claims. For example, although the present invention has been described in the context of a smoke emergency in an airplane cockpit, the present invention may be used any application where it is desired to have smoke-free viewing.

What is claimed is:

1. A smoke-free viewing apparatus, comprising:
an expandable enclosure being expandable between a collapsed position and an expanded position, said expandable enclosure defining a smoke-free interior area when in said expanded position, said expandable enclosure having at least one transparent section that allows viewing in said smoke-free interior area; and
an electronic device disposed in said smoke-free interior area of said expandable enclosure, said electronic device having a display,
wherein said display of said electronic device is viewable through said at least one transparent section from outside of said expandable enclosure.

2. A smoke-free viewing apparatus according to claim 1, wherein
said electronic device is one of a tablet computer, radio, and cellular telephone.

3. A smoke-free viewing apparatus according to claim 1, wherein
said expandable enclosure is inflated from said collapsed position to said expanded position.

4. A smoke-free viewing apparatus according to claim 1, wherein
said expandable enclosure is manually pulled from said collapsed position to said expanded position.

5. A smoke-free viewing apparatus according to claim 4, wherein
said expandable enclosure includes a spring member, and
said spring member facilitates expansion of said enclosure from said collapsed position to said expanded position.

6. A smoke-free viewing apparatus according to claim 1, wherein
said expandable enclosure includes at least one pocket that is extendable into said smoke-free interior area, said pocket reaching said electronic device.

7. A smoke-free viewing apparatus according to claim 6, wherein
said pocket is located in a side wall or a bottom wall of said expandable enclosure.

8. A smoke-free viewing apparatus according to claim 1, wherein
said expandable enclosure includes at least one filter member.

9. A smoke-free viewing apparatus according to claim 1, wherein
said expandable enclosure includes another transparent wall opposite said at least one transparent wall, and said electronic device is disposed between said transparent walls.

10. A smoke-free viewing apparatus according to claim 1, wherein
said expandable enclosure includes at least one support member for supporting said electronic device.

11. A smoke-free viewing apparatus according to claim 10, wherein
said support member is a strap located in said smoke-free interior area.

12. A smoke-free viewing apparatus according to claim 1, wherein
said smoke-free interior area of said expandable enclosure includes a groove for holding said electronic device.

13. A smoke-free viewing apparatus for an airplane cockpit, comprising:
an expandable enclosure expandable between a collapsed position and an expanded position, said expandable enclosure being configured to fit in the airplane cockpit when said expandable enclosure is in said expanded position, said expandable enclosure defining a smoke-free interior area when in said expanded position, and said expandable enclosure having at least one transparent section that allows viewing both in said smoke-free interior area and through said expandable enclosure; and
an electronic device disposed in said smoke-free interior area of said expandable enclosure, said electronic device having a display,
wherein said display of said electronic device is viewable through said at least one transparent section from outside of said expandable enclosure.

14. A smoke-free viewing apparatus according to claim 13, wherein
said electronic device is a tablet computer.

15. A smoke-free viewing apparatus according to claim 13, wherein
said expandable enclosure is inflated from said collapsed position to said expanded position.

16. A smoke-free viewing apparatus according to claim 13, wherein
said expandable enclosure is manually pulled from said collapsed position to said expanded position.

17. A smoke-free viewing apparatus according to claim 13, wherein
said expandable enclosure includes a plurality of pockets that is extendable into said smoke-free interior area, said pockets reaching said electronic device.

18. A smoke-free viewing apparatus according to claim 17, wherein
said pockets are located in opposite side walls of said expandable enclosure.

19. A smoke-free viewing apparatus according to claim 13, wherein
said expandable enclosure includes at least one filter member.

20. A smoke-free viewing apparatus according to claim 13, wherein
said expandable enclosure includes at least one strap for supporting said electronic device.

21. A smoke-free viewing apparatus according to claim 13, wherein
said smoke-free interior area supports a second electronic device.

22. A smoke-free viewing apparatus according to claim 21, wherein
said second electronic device is a cellular telephone.

23. A smoke-free viewing apparatus for an airplane cockpit, comprising:
an expandable enclosure expandable between a collapsed position and an expanded position, said expandable enclosure being configured to fit in the airplane cockpit when said expandable enclosure is in said expanded position, said expandable enclosure defining a smoke-free interior area when in said expanded position, and said expandable enclosure being substantially transparent, thereby allowing viewing both in said smoke-free interior area from outside of said expandable enclosure and through said expandable enclosure to the outside;
at least one pocket disposed on said expanding enclosure, said at least one pocket being extendable into said smoke-free interior area; and
a tablet computer disposed in said smoke-free interior area of said expandable enclosure,
wherein said tablet computer is viewable in said smoke-free interior area from outside of said expandable enclosure and said at least one pocket is reachable to said tablet computer allowing manipulation thereof.

24. A smoke-free viewing apparatus according to claim 23, wherein
said expandable enclosure is inflated from said collapsed position to said expanded position.

25. A smoke-free viewing apparatus according to claim 23, wherein
said expandable enclosure is manually pulled from said collapsed position to said expanded position.

26. A smoke-free viewing apparatus according to claim 23, wherein
said expandable enclosure includes a plurality of pockets extendable into said smoke-free interior area.

27. A smoke-free viewing apparatus according to claim 23, wherein
said expandable enclosure includes at least one filter member.

28. A smoke-free viewing apparatus according to claim 23, wherein
said smoke-free interior area of said expandable enclosure includes at least one strap for supporting said tablet computer.

29. A smoke-free viewing apparatus according to claim 23, wherein
said smoke-free interior area of said expandable enclosure supports a second electronic device.

30. A smoke-free viewing apparatus according to claim 29, wherein
said second electronic device is a cellular telephone.

31. A smoke-free viewing apparatus according to claim 23, wherein
said expandable enclosure includes first and second channels, said first channel being adapted to be positioned next to a front windshield of the airplane cockpit and said second channel being adapted to be positioned next to a instrument panel of the airplane cockpit.

32. A method for deploying a smoke-free viewing apparatus for an airplane cockpit,
comprising the steps of:
providing an expandable enclosure expandable between a collapsed position and an expanded position, the expandable enclosure being configured to fit in the airplane cockpit when the expandable enclosure is in the expanded position, the expandable enclosure defining a smoke-free interior area when in the expanded position, and the expandable enclosure being substantially transparent;
manually expanding the expandable enclosure to the expanded position;
inserting a tablet computer into the smoke-free interior area expandable enclosure; and
viewing the tablet computer in the smoke-free interior area from outside of the expandable enclosure.

33. A method according to claim 32, further comprising the steps of:
viewing through the enclosure from outside of the enclosure to a windshield of the airplane cockpit.

34. A method according to claim 33, further comprising the steps of:
providing at least one pocket disposed on the expanding enclosure; and
sing the pocket to manipulate the tablet computer.

35. A method according to claim 34, further comprising the step of:
filtering the interior area of the enclosure.
